(19) United States
(12) Patent Application Publication
(10) Pub. No.: US 2025/0282171 A1
(43) Pub. Date: Sep. 11, 2025

(54) MOBILE DEVICE AND MOBILE DEVICE MODEL AND METHOD OF INSET STONES THEREOF

(71) Applicants: SHENZHEN TINNO WIRELESS TECHNOLOGY CO., LTD., Shenzhen (CN); SHENZHEN TINNO MOBILE TECHNOLOGY CO., LTD., Shenzhen (CN)

(72) Inventors: WEN-HUA DENG, Shenzhen (CN); FENG-QIU QIU, Shenzhen (CN); XIAO-LIN DONG, Shenzhen (CN)

(21) Appl. No.: 18/664,250

(22) Filed: May 14, 2024

(30) Foreign Application Priority Data
Mar. 11, 2024 (US) 29/932068
Apr. 3, 2024 (CN) 202410408861.7
Apr. 3, 2024 (US) 29/935623

(51) Int. Cl. B44B 9/00

(52) U.S. Cl. CPC B44B 9/00

(57) ABSTRACT

A mobile device frame for wrapping a mobile device, the mobile device providing with at least one function key, a charger jack, at least one speaker hole and an antenna module on a side, comprising: a frame comprising a top wall, a bottom wall and two side walls, which together enclose and form a holding slot, the holding slot being formed with at least one perforation and at least one inset slot, the perforations being disposed respectively on the function keys, the charger jack, the speaker hole, and the antenna module, the inset slot being surrounded by at least one claw, the inset slot and the perforation being separate and together covering the sides of the inset slot; and at least one ornament, embedded in the inset slot.

### CROSS-REFERENCE TO RELATED APPLICATION

This application claims the benefit of US Design patent application Ser. No. 29/932,068, filed on Mar. 11, 2024, US Design patent application Ser. No. 29/935,623, filed on Apr. 3, 2024, and China Patent Application No. 202410408861.7, filed on Apr. 3, 2024, which are hereby incorporated by reference for all purposes as if fully set forth herein.

### TECHNICAL FIELD

The present invention is mainly in the technical field of a mobile device processing equipment, and in particular there is about a mobile device and a mobile device model and its stone inset method.

### BACKGROUND ART

In the era of advanced electronic technology industry, mobile devices such as mobile phones and tablet computers have become indispensable necessities for people. Since the mobile devices are mostly operated by holding them in the hand, there is a high chance that the mobile devices will be dropped accidentally. Therefore, most people will install a protective case on the exterior of the mobile devices to prevent the mobile devices from being damaged due to dropping or scratches.

At the same time, as the popularity of the mobile devices increases, people's demand for the aesthetic appearance of the mobile devices also increases. However, although prior art protective cases such as transparent protective cases can protect the mobile device to a certain extent, their appearance visually does not satisfy the consumer needs of a certain group of people.

### INVENTION CONTENTS

It is an object of the present invention to provide a mobile device and a mobile device model and a stone-inset method thereof, which can be set with ornaments such as crystals, diamonds or gemstones to satisfy the consumption needs of a specific group of people.

In order to achieve the above object, the present invention provides a method of stone-inset a mobile device, characterized in that it comprises the steps of: providing a mobile device and fixing said mobile device using a fixture, said mobile device being provided with at least one function key, a charger jack, at least one speaker hole, and an antenna module; providing a drilling and milling device and machining a side of said mobile device with said drilling and milling device in order to form at least one inset slot, and to process at least one claw around the perimeter of said inset slot, said inset slot being separate from each of said function key, said charger jack, said speaker hole, and said antenna module, and together covering the side edge of said mobile device; and to provide a press-fit device, and to provide at least one ornament, said press-fit device to press said ornament into said inset slot, and to cause said claws to be deform to secure said ornament in said inset slot by means of a claw-set inset.

The present invention also provides a method of stone inset for a mobile device model, characterized in that it comprising: providing a model and a mobile device model, said model comprising a top wall, a bottom wall, and two side walls, which together enclose to form a holding slot, said mobile device model being provided with at least one function key, a charger jack, at least one speaker hole, and an antenna module, and fixing said model using a fixture; providing a drilling and milling device and machining on said holding slot with said drilling and milling device to form at least one perforation hole, the positions of said perforation holes corresponding to the positions of said function keys, said charger jack, said speaker holes, and said antenna module, respectively, in said model of a mobile device; using a set of fitting device, tucking said model of a mobile device into said holding slot such that said top wall, said bottom wall, and said side walls to fit over the sides of said mobile device model, respectively; using a drilling and milling device to further process said holding slot to form at least one inset slot, and to process at least one claw around said inset slot, said inset slot being separate from said perforations and together filling said holding slot; and to provide a press-fit device, and to provide at least one ornament, said press-fit device pressing said ornament into said inset slot and deforms said claws to secure said ornament in said inset slot by means of a claw-set inset.

In some embodiments, said press-fit means is to press one ornament at a time into said inset slot, or at least one ornament at a time simultaneously into said inset slot.

In some embodiments, said drilling and milling means processes said claws so that the appearance of said claws away from said inset slots forms an arc or a right angle.

The present invention further provides a mobile device characterized in that it comprises: at least one function key located on a side of said mobile device; a charger jack located on a side of said mobile device; at least one speaker hole located on a side of said mobile device; an antenna module provided closer to a side of said mobile device; and at least one ornamentation, wherein the side of said mobile device has at least a inset slot, said inset slot being provided with at least one claw around the surrounding area, said inset slot being separate from each of said function key, said charger jack, said speaker hole and said antenna module, and together covering the side of said mobile device, said ornament being inset in said inset slot.

The present invention also provides a mobile device model for wrapping a mobile device, said mobile device having at least one function key, a charger jack, at least one speaker hole and an antenna module on the side of said mobile device, characterized in that it comprising: a model comprising a top wall, a bottom wall and two side walls, which together enclose and form a holding slot, at least one perforation and at least one insertion slot formed in said holding slot, said perforations disposed opposite said function key, said charger jack, said speaker hole and said antenna module, respectively, said inset slot being surrounded by at least one claw, said inset slot being separate from said perforation and collectively covering the sides of said holding slot; and at least one ornament, inset within said inset slot.

In some embodiments, said model is made of a metallic material.

In some embodiments, said mobile device is a mobile phone or a tablet computer.

In some embodiments, the number of said claws are four or six.

In some embodiments, said ornament is a crystal, a diamond or a gemstone.

In some embodiments, the appearance of said claws away from said inset slots forms a rounded shape or a straight angled shape.

The mobile device model of the present invention has the following features: the mobile device of the present invention and the stone-setting method thereof with the mobile device model and the stone-setting method thereof are capable of enhancing the aesthetic appearance of the mobile device, the mobile device model as a whole by insetting the ornaments such as crystals, diamonds, or gemstones into said inset slot in order to satisfy the consumer needs of a specific group of people, and serves the purpose of ornamenting said mobile device, and at the same time, due to the presence of said ornament, avoiding the phenomenon that the surface of the model of the mobile device in the prior art is too smooth, and it is easy to slip from the hand and break the mobile phone.

### BRIEF DESCRIPTION OF THE DRAWINGS

FIG. 1 is a method flow chart of the method of setting stones for a mobile device of the present invention;

FIG. 2 is a diagram of the use of the fixing step of the method of setting stones for the mobile device of the present invention;

FIG. 3 is a diagram of a processing step of the method for setting a stone in a mobile device of the present invention;

FIG. 4 shows a diagram of the use of the press-fit step of the method for setting stones of the mobile device of the present invention;

FIG. 5 shows a three-dimensional combination of the mobile device of the present invention;

FIG. 6 is a three-dimensional exploded view of the mobile device of the present invention;

FIG. 7 shows a method flow chart of the method of setting stones in the model of the mobile device of the present invention;

FIG. 8 shows a diagram of the use of the fixing step of the method of setting stones in the model of the mobile device of the present invention;

FIG. 9 is a diagram showing the use of the first processing step and the second processing step of the method of setting stones in the model of the mobile device of the present invention;

FIG. 10 is a diagram of the use of the fitting step of the method of setting a stone in a mobile device of the present invention;

FIG. 11 shows a diagram of the use of the press-fit step of the method of setting stones in the model of the mobile device of the present invention;

FIG. 12 shows a three-dimensional combination of the mobile device model of the present invention;

FIG. 13 is a three-dimensional exploded view of the mobile device model of the present invention.

### DETAILED DESCRIPTION OF THE EMBODIMENTS

Now with the drawings will be embodiments of the present invention is described in detail as follows, the attached drawings are mainly simplified schematic diagrams, only schematically illustrate the basic structure of the present invention, so in these drawings only marked with the invention of the components, and the components shown are not the implementation of the number of components, shapes, sizes, proportions and so on to be drawn, and the actual implementation of the specifications of the dimensions of the actual design of a selective, and the layout of the components may be more complex.

The following embodiments are described with reference to additional drawings to exemplify particular embodiments in which the present invention may be implemented. Orientation terms such as “up”, “down”, “front”, “back”, etc., are used in the present invention only with reference to the orientation of the additional drawings. Accordingly, the directional terms used are intended to illustrate and understand the present application and are not intended to limit the present application. Furthermore, in the specification, the word “including” will be understood to mean including the described components, but not excluding any other components, unless explicitly described to the contrary.

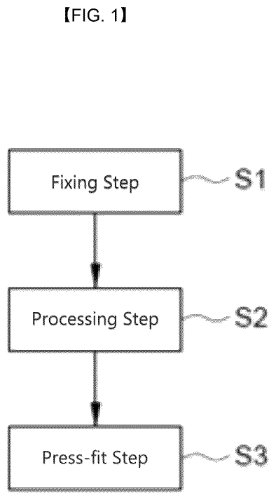

Referring to FIG. 1, there is shown a flowchart of a specific embodiment of a method for setting stones in a mobile device of the present invention, comprising the following steps: a fixing step S1, a processing step S2 and a press-fit step S3.

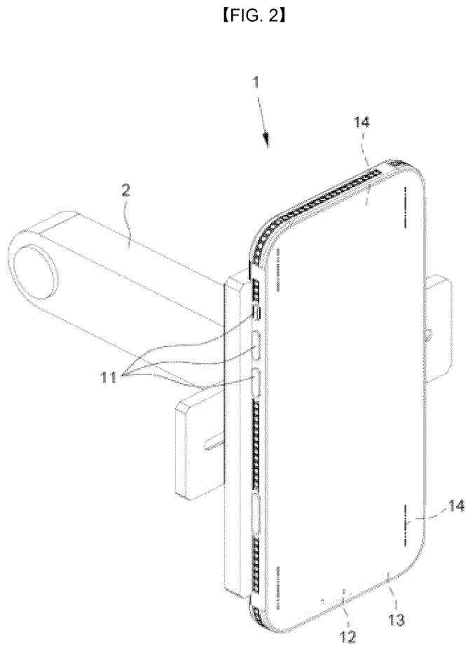

Referring to FIG. 2 together, said fixing step S1 consists of providing a mobile device 1 and fixing said mobile device 1 with a fixture 2. In some embodiments, said mobile device is a mobile phone or a tablet computer, and said fixture 2 can be a robotic arm and automatically complete the operation by means of an automated control system. In detail, said mobile device 1 is provided with at least one function key 11, a charger jack 12, at least one speaker hole 13 and an antenna module 14.

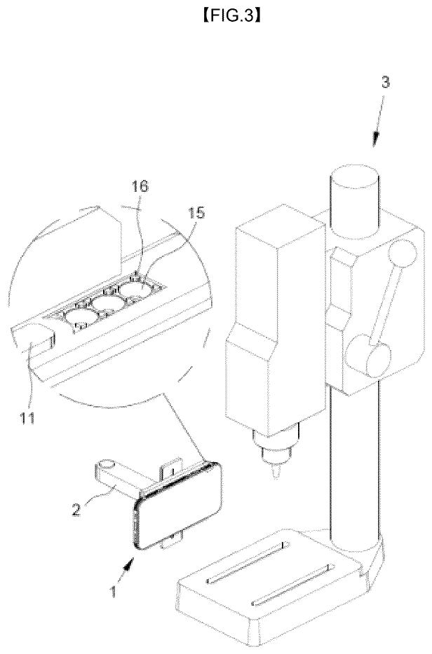

Referring to FIG. 3, said processing step S2 is to provide a drilling and milling device 3 and to process the side of said mobile device 1 with said drilling and milling device 3 to form at least one inset slot 15 and to process around said inset slot 15 to form at least one claw 16, and in some embodiments, the number of said claws 16 may be four or six. In detail, said inset slot 15 is separate from each of said function key 11, said charger jack 12, said speaker hole 13 and said antenna module 14, and together they cover the side of said mobile device 1. In some embodiments, said drilling and milling device 3 may further process said claws 16 so that the appearance of said claws 16 away from said inset slot 15 forms a circular arc or a straight corner.

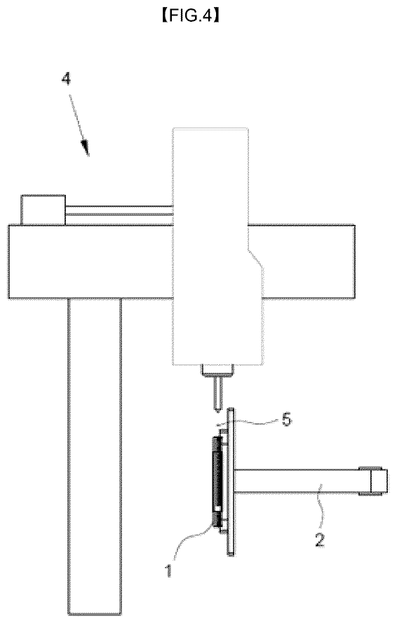

Referring to FIG. 4, said press-fit step S3 is to provide a press-fit device 4 with at least one ornament 5, in some embodiments said ornament 5 may be a crystal, diamond or gemstone. In detail, said press-fit device 4 presses said ornament 5 into said inset slot 15 and deforms said claws 16 to secure said ornament in said inset slot 15 by means of a claw-set inset, and in some embodiments, said press-fit device 4 may be for pressing one ornament 5 at a time into said inset slot 15, or for pressing at least one ornament 5 at a time at the same time into said inset slot 15.

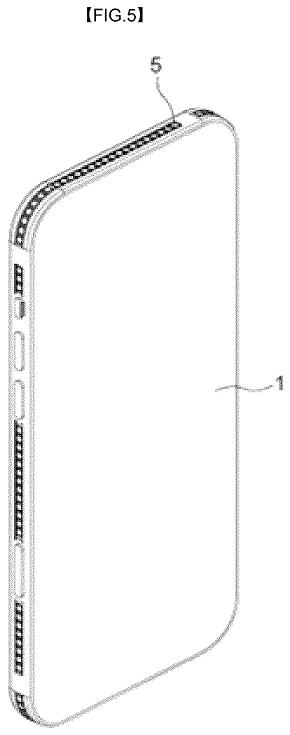

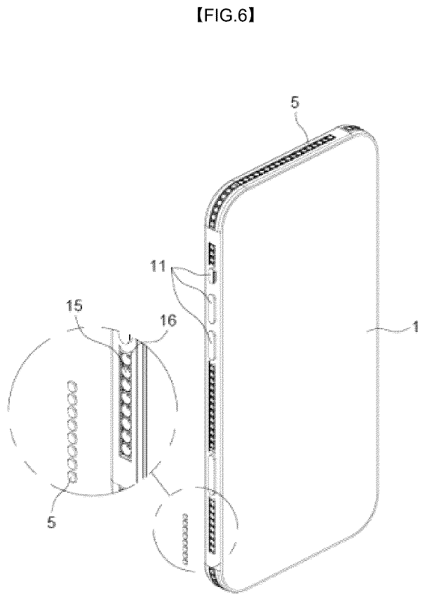

Referring to FIGS. 5 and 6, there is a mobile device 1 manufactured according to the mobile device stone setting method of the present invention, comprising: a said function key 11, a said charger jack 12, a said speaker hole 13, and a said antenna module 14, wherein said function key 11, said charger jack 12, and said speaker hole 13 are provided, respectively, at a side of said mobile device 1, and said antenna module 14 is provided more proximate to said side of said mobile device 1 are provided. Said mobile device 1 has a side edge with said inset slot 15, said inset slot 15 is surrounded by said claws 16, said claws 16 forming a rounded shape or a straight angled shape away from the appearance of said inset slot 15. Said inset slot 15 is separate from each of said function key 11, said charger jack 12, said speaker hole 13 and said antenna module 14, and together they cover the side of said mobile device 1. Said ornament 5 is inset into said inset slot 15 to complete said mobile device 1.

In some embodiments, the backside of said mobile device 1 also has at least one of said inset slot 15, and said ornament 5 is inset in said inset slot 15 of said mobile device 1 located on the side and the backside, respectively.

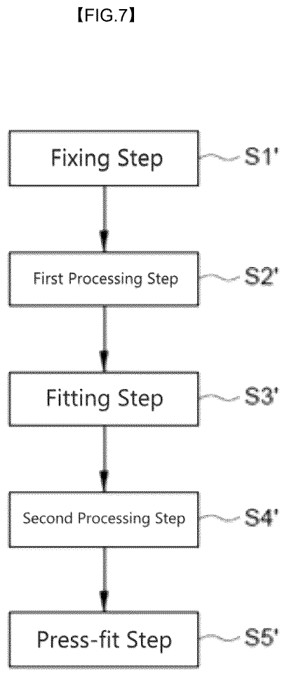

Referring to FIG. 7, there is shown a method flowchart of a specific embodiment of the method of stone setting for a mobile device model of the present invention, which comprises the following steps: a fixing step S1′, a first processing step S2′, a fitting step S3′, a second processing step S4′ and a press-fit step S5′.

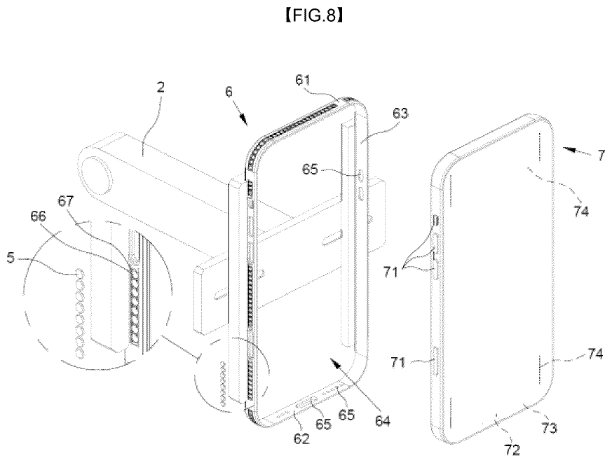

Referring to FIG. 8 together, said fixing step S1′ is to provide a frame 6 and a mobile device model 7, wherein said frame 6 comprises a top wall 61, a bottom wall 62 and two side walls 63, which together enclose a holding slot 64, and wherein in some embodiments said frame 6 is made of an elastic material. Said mobile device model 7 is provided with at least one function keys 71, a charger jack 72, at least one speaker hole 73, and an antenna module 74. further, said frame 6 is fixed using the foregoing fixture 2.

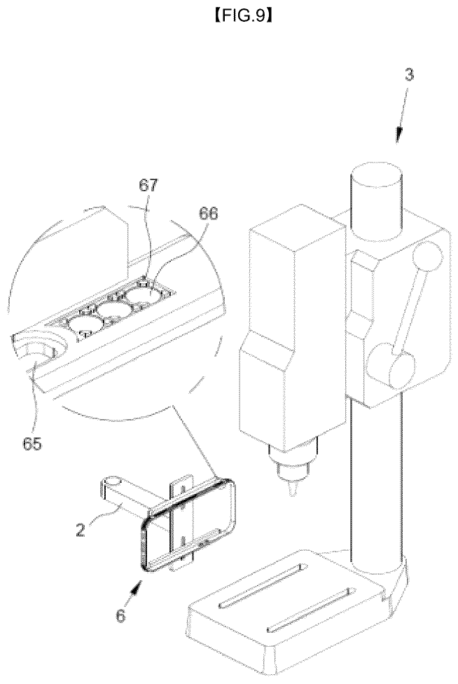

Referring to FIG. 9, said first processing step S2′ is to provide said drilling and milling device 3 and to process with said drilling and milling device 3 on said holding slot 64 to form at least one perforation 65. the position of said perforation 65 corresponds to the position of said function keys 71, said charger jack 72, said speaker hole 73, and said antenna module 74, respectively, at the setup position of said mobile device model 7, in some embodiments, said perforation 65 for said function keys 71 is provided in said side wall 63, said perforation 65 for said charger jack 72 is provided in said bottom wall 62, said perforation 65 for said speaker hole 73 is provided in said bottom wall 62, and said perforation 65 for said antenna module 74 may be provided in said top wall 61 or/and bottom wall 62.

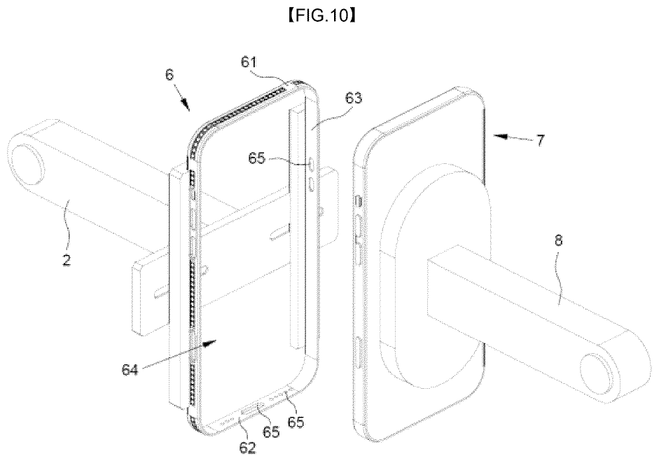

Referring to FIG. 10, said fitting step S3′ is to use a fitting device 8 to tuck said mobile device model 7 into said holding slot 64 so that said top wall 61, said bottom wall 62 and said side wall 63 are each fitted to a side of said mobile device model 7.

Referring again to FIG. 9, said second processing step S4′ is to use said drilling and milling device 3 to further process on said holding slot 64 to form at least one inset slot 66 and to process around said inset slot 66 to form at least one claw 67, and in some embodiments the number of said claws 67 may be four or six. In detail, said inset slots 66 and said perforations 65 are each separate and together cover said holding slots 64. in some embodiments, said drilling and milling device 3 may further process said claws 67 so that the appearance of said claws 67 away from said inset slots 66 forms a rounded or straight angled shape.

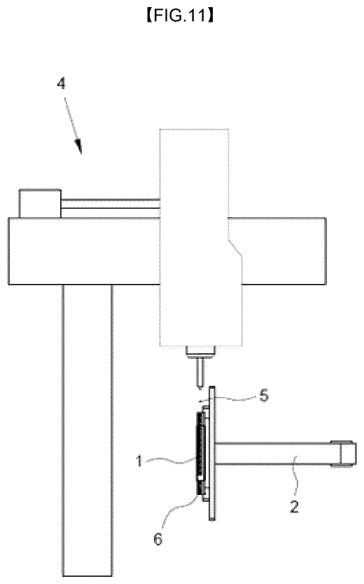

Referring to FIG. 11, said press-fit step S5′ is to provide said press-fit device 4 with at least one of said ornament 5. in detail, said press-fit device 4 presses said ornament 5 into said inset slot 66 and deforms said claws 67 to secure said ornament in said inset slot 66 in a claw-set inset, in some embodiments, said press-fit device 4 may be for pressing one ornament 5 at a time into said inset slot 66, or at least one ornament 5 at a time at the same time into said inset slot 66.

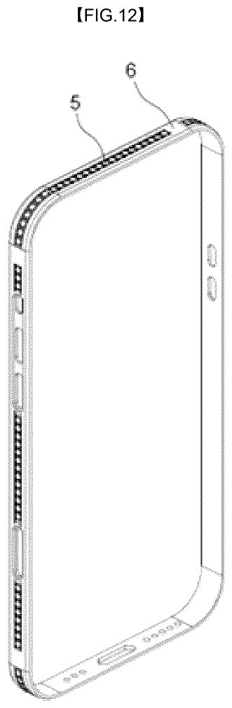

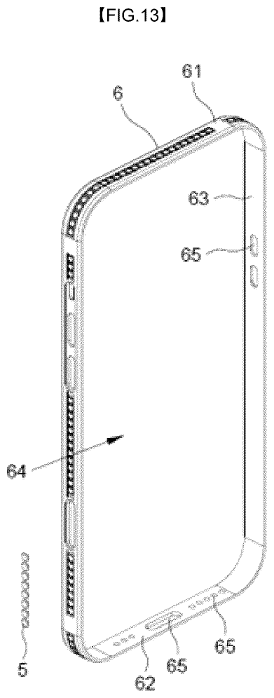

Referring to FIGS. 12 and 13, there is shown a frame 6 manufactured according to the mobile device model inset method of the present invention for encasing a mobile device, said mobile device being provided with at least one function key, a charger jack, at least one speaker hole, and an antenna module on the side of said mobile device, and said frame 6 comprising: a foregoing top wall 61, a foregoing bottom wall 62, and a foregoing side wall 63, which together enclose to form a foregoing holding slot 64. said holding slot 64 is formed on at least one of said holding slots 64, which is formed on at least one of said holding slots 64. At least one of said perforations 65 and at least one of said inset slots 66 are formed in said holding slot 64, said perforations 65 being disposed opposite said function keys, said charger jack, said speaker hole and said antenna module, respectively, and said inset slots 66 are surrounded by said claws 67, said claws 67 having a rounded shape or straight angled shape away from said inset slots 66. Said inset slot 66 and said perforations 65 are each separate and together cover the sides of said holding slot 64. The ornaments 5 are embedded in said inset slots 66 to complete the manufacture of said frame 6.

Following the foregoing, the mobile device of the present invention and the stone-setting method thereof and the mobile device model and the stone-setting method thereof are capable of enhancing the aesthetic appearance of the mobile device, the mobile device model as a whole by setting ornaments such as crystals, diamonds or gemstones in said inset slots to satisfy the consumer needs of a particular group of people, and serve to adorn said mobile device, and at the same time, also, due to the presence of said ornaments, to avoid the phenomenon that the surface of the mobile device model in the prior art is too smooth, and it is easy to slip from the hand and break the mobile phone.

The above-disclosed embodiments are only illustrative of the principles, features, and effects of the present invention, and are not intended to limit the scope of implementation of the present invention, and any person skilled in the art may modify and change the above embodiments without violating the spirit and scope of the present invention. Any equivalent changes and modifications made by applying the disclosed contents of the present invention shall still be covered by the scope of the attached patent application.

What is claimed is:

1. A method of stone inset for a mobile device, comprising:
providing a mobile device and securing it using a fixture, the mobile device being provided with at least one function key, a charger jack, at least one speaker hole and an antenna module;
providing a drilling and milling device and processing a side of the mobile device with the drilling and milling device to form at least one inset slot and processing a surrounding of the inset slot to form at least one claw, the inset slot being separate from each of the function key, the charger jack, the speaker hole, and the antenna module, and collectively covering the side of the mobile device; and
providing a press-fit device and providing at least one ornament, the press-fit device pressing the ornament into the inset slot and deforming the claws to secure the ornament in the inset slot by means of a claw-set inset.

2. The method of stone inset for a mobile device of claim 1, characterized in that the fixture is a robotic arm and the work is done automatically by means of an automated control system.

3. The method of stone inset for a mobile device of claim 1, characterized in that the press-fit device is for pressing one ornament at a time into the inset slot, or at least one ornament at a time at the same time into the inset slot.

4. The method of stone inset for a mobile device of claim 1, characterized in that the drilling and milling device processes the claws so that the appearance of the claws away from the inset slots forms a rounded shape or a straight angled shape.

5. A mobile device, comprising:
at least one function key, located on a side of the mobile device;
a charger jack, located on the side of the mobile device;
at least one speaker hole, located on the side of the mobile device;
an antenna module, provided closer to the side of the mobile device; and
at least one ornament, wherein the side edge of the mobile device has at least one inset slot, the inset slot being provided with at least one claw around the periphery of the inset slot, the inset slot being separate from each of the function key, the charger jack, the speaker hole, and the antenna module, and together covering the side edge of the mobile device, and the ornament being embedded in the inset slot.

6. The mobile device of claim 5, characterized in that the mobile device is a mobile phone or a tablet computer.

7. The mobile device of claim 5, characterized in that the number of the claws are four or six.

8. The mobile device of claim 5, characterized in that the ornament is a crystal, a diamond or a gemstone.

9. The mobile device of claim 5, characterized in that the appearance of the claws away from the inset slots forms a rounded shape or a straight angled shape.

10. The mobile device of claim 5, characterized in that the back of the mobile device also has at least one the inset slot, the ornament being inset in the inset slots of the mobile device situated on the side and on the back of the mobile device, respectively.

11. A method of stone inset a mobile device frame, comprising:
Providing a frame and a mobile device model, the frame comprising a top wall, a bottom wall and two side walls together enclosing to form a holding slot, the mobile device model being provided with at least one function key, a charger jack, at least one speaker hole and an antenna module, and fixing the frame using a fixture;
Providing a drilling and milling device and machining the drilling and milling device on the holding slot to form at least one perforation, the perforation being at a position corresponding to the position of the function key, the charger jack, the speaker hole, and the antenna module, respectively, in the model of a mobile device;
using a fitting device, tucking the mobile device model into the holding slot such that the top wall, the bottom wall, and the side walls fit against the sides of the mobile device model, respectively;
using a drilling and milling device to further process the holding slot to form at least one inset slot and to process at least one claw around the surrounding area of the inset slot, the inset slot being separate from the perforations and together covering the holding slot; and
providing a press-fit device and providing at least one ornament, the press-fit device pressing the ornament into the inset slot and deforming the claws to secure the ornament in the inset slot by means of a claw-set inset.

12. The method of stone inset a mobile device frame of claim 11, characterized in that the fixture is a robotic arm and automatically completes the operation by means of an automated control system.

13. The method of stone inset a mobile device frame of claim 11, characterized in that the press-fit device is one that presses one ornament at a time into the inset slot, or at least one ornament at a time at the same time into the inset slot.

14. The method of stone inset a mobile device frame of claim 11, characterized in that the drilling and milling means processes the claws so that the appearance of the claws away from the inset slots forms a rounded shape or a straight angled shape.

15. A mobile device frame for wrapping a mobile device, the mobile device being provided with at least one function key, a charger jack, at least one speaker hole and an antenna module on a side, characterized in:
a frame comprising a top wall, a bottom wall and two side walls, together enclosing and forming a holding slot, the holding slot forming at least one perforation and at least one inset slot, the perforations being disposed opposite to the function key, the charger jack, the speaker hole and the antenna module, respectively, the inset slots being provided with at least one claw around the periphery of the inset slots, the inset slots being separate from each of the perforations and together covering the sides of the holding slot; and
at least one ornament, embedded in the inset slot.

16. The mobile device frame of claim 15, characterized in that the mobile device is a mobile phone or a tablet computer.

17. The mobile device frame of claim 15, characterized in that the number of the claws are four or six.

18. The mobile device frame of claim 15, characterized in that the ornament is a crystal, a diamond, or a gemstone.

19. The mobile device frame of claim 15, characterized in that the appearance of the claws away from the inset slots forms a rounded shape or a straight angled shape.
